(19) United States
(12) Patent Application Publication
(10) Pub. No.: US 2024/0371559 A1
(43) Pub. Date: Nov. 7, 2024

(54) DIGITAL DEVICE, METHOD FOR PRODUCING SAME, AND METHOD FOR USING SAME

(71) Applicant: TOHOKU UNIVERSITY, Sendai-shi, Miyagi (JP)

(72) Inventors: Yutaro TAKEUCHI, Miyagi (JP); Shunsuke FUKAMI, Miyagi (JP); Yuta YAMANE, Miyagi (JP); Jun'ichi IEDA, Ibaraki (JP); Ju-Young YOON, Miyagi (JP); Butsurin JINNAI, Miyagi (JP); Shun KANAI, Miyagi (JP); Hideo OHNO, Miyagi (JP)

(21) Appl. No.: 18/555,694

(22) PCT Filed: Jan. 7, 2022
(86) PCT No.: PCT/JP2022/000297

§ 371 Date: Oct. 16, 2023

(30) Foreign Application Priority Data
Apr. 21, 2021 (JP) 2021-071582

(51) Int. Cl. H01F 10/32; G06F 7/58; G11C 11/16; H01F 41/22

(52) U.S. Cl. CPC H01F 10/329; G06F 7/588; G11C 11/1675; H01F 10/3254; H01F 41/22

(57) ABSTRACT

A purpose is to provide an electronic device that can be used as a memory device or a random number generation device capable of outputting a relatively large reading signal, and that can also be used as an oscillation/wave detection device having output/input frequency variability, without requiring an external magnetic field. Provided is an electronic device characterized by including a body, input terminals, and output terminals, in which the body is configured by laminating a spin-torque generation layer and a non-collinear antiferromagnetic layer on a substrate in such an order or in a reverse order in a laminating direction, the input terminals are disposed on both ends of the spin-torque generation layer in any one direction parallel to a lamination surface, and the non-collinear antiferromagnetic layer has a non-collinear magnetic order in a surface formed by said any direction and the laminating direction.

### TECHNICAL FIELD

The present invention relates to an electronic device, a method for producing the same, and a method for using the same.

### BACKGROUND ART

A magnetic order of a magnetic material is classically controlled by a magnetic field. In recent years, along with development of a spintronics technique that simultaneously utilizes an electrical property (charge) and a magnetic property (spin) of electrons, various attempts have been made to control the magnetic order of the magnetic material by an electric current. Such a phenomenon is caused by exchange of angular momentum between a magnetic moment that constitutes the magnetic order and spin of conduction electrons. A torque acting on the magnetic order when the electric current is introduced is called a spin-transfer torque (STT), or simply a spin-torque.

NPL 1 first reports a magnetic order of a ferromagnetic body, that is, an experimental result relating to an inversion of a magnetization direction by a spin-transfer torque. The phenomenon is called spin-transfer torque-induced magnetization reversal or the like. The spin-transfer torque magnetization reversal can be used for a method of writing information to a magnetoresistive random access memory (MRAM). The technique has been put to practical use as STT-MRAM.

Next, NPL 2 reports that steady (direct current) spin-transfer torque can induce an oscillation at a constant cycle in magnetization of a ferromagnetic body. The phenomenon is called spin-torque oscillation or the like. It is characterized in that an alternating voltage is output when a direct current is introduced.

Regarding the spin-torque oscillation phenomenon, it is known that when a plurality of ferromagnetic bodies have a spin-transfer torque acting thereon, and are close to each other or are electrically connected, the ferromagnetic bodies oscillate in the same phase (i.e., are synchronized), and output an alternating voltage having a larger amplitude in a narrower frequency range. NPL 3 reports an experimental result thereof. In general, a ratio of an output amplitude intensity to a half width of an oscillation frequency in an oscillation device or an oscillation circuit is called a Q value, and a synchronization phenomenon brings about an increase in the Q value, that is, improves a performance of the oscillation device.

It is also known that as an inverse effect of the spin-torque oscillation, when a spin-transfer torque oscillating at a constant cycle is applied to the magnetization of a ferromagnetic body, the magnetization of the ferromagnetic body resonates and moves at a certain frequency, and a direct voltage is output. NPL 4 reports an experimental result thereof. The phenomenon is called spin-torque ferromagnetic resonance or the like. It is characterized in that a direct voltage is output when an alternating current is introduced.

Phenomena such as the spin-torque oscillation and the synchronization phenomenon thereof, and the spin-torque ferromagnetic resonance are expected to be applied to a communication technique such as transmission and reception of electromagnetic wave, radar, nondestructive inspection, clock of electronic circuit, microwave assisted magnetic recording in hard disk drive, energy harvesting, brain-type computer, and the like, and have been subjected to active research and development. These techniques have advantages such as being able to realize the same function in a smaller area than the existing technologies, and being able to be produced at a low cost.

In addition, a random number generator utilizing a spin-torque magnetization reversal probability or a heat fluctuation of magnetization of a ferromagnetic body is also proposed and subjected to research and development. An output random number is an intrinsic physical random number and thus is unpredictable, which also has an advantage of being able to be implemented by a fine device. In addition to a security technique, as disclosed in NPL 5, in recent years, a possibility of application to non-traditional computing techniques is also demonstrated and subjected to research and development.

Incidentally, in addition to a ferromagnetic body in which a net magnetization is spontaneously expressed by spins aligned in parallel (or aligned with a parallel component), magnetic bodies having a magnetic order include an antiferromagnetic body which does not have a net magnetization because adjacent spins are aligned in a direction in which the spins cancel each other out. Further, the antiferromagnetic body is classified into collinear antiferromagnetic bodies in which the net magnetization is zero because adjacent spins are aligned antiparallel to each other and non-collinear antiferromagnetic bodies in which the net magnetization is zero (or nearly zero) because three or more adjacent spins are aligned non-collinearly.

In the related art, since the antiferromagnetic body does not have net (macro) magnetization, it has been recognized that it is difficult to control the electrical magnetic order based on the law of conservation of angular momentum. NPL 6 discloses that a magnetic order (Neel vector) of the collinear antiferromagnetic body can be rotated by 90 degrees by using a spin-orbit torque which is a spin-transfer torque expressed by quantum relativistic effect.

Subsequently, NPL 7 discloses that a magnetic moment of each sub-lattice of a non-collinear antiferromagnetic body can be reversed by 180 degrees by using a spin-orbit torque in the same manner. However, current control of a magnetic order of the non-collinear antiferromagnetic body shown in NPL 7 actually constructs a structure of a device and control for the device such that the same action mechanism can be implemented as the current control of the magnetic order of a ferromagnetic body, which does not take advantage of a unique behavior of the non-collinear antiferromagnetic body. In addition, the current control shown in NPL 7 is based on a premise of presence of a stationary magnetic field, though the reason thereof is omitted.

### CITATION LIST

### Non Patent Literature

NPL 1: E. B. Myers, D. C. Ralph, J. A. Katine, R. N. Louie, and R. A. Buhrman, “Current-Induced Switching of Domains in Magnetic Multilayer Devices,” Science, vol. 285, pp. 867-870 (1999).
NPL 2: S. I. Kiselev, J. C. Sankey, I. N. Krivorotov, N. C. Emley, R. J. Schoelkopf, R. A. Buhrman, and D. C. Ralph, “Microwave oscillations of a nanomagnet driven by a spin-polarized current,” Nature, vol. 425, pp. 380-383 (2003).
NPL 3: S. Kaka, M. R. Pufall, W. H. Rippard, T. J. Silva, S. E. Russek, and J. A. Katine, “Mutual phase-locking of microwave spin torque nano-oscillators,” Nature, vol. 437, pp. 389-392 (2005).
NPL 4: A. A. Tulapurkar, Y. Suzuki, A. Fukushima, H. Kubota, H. Maehara, K. Tsunekawa, D. D. Djayaprawira, N. Watanabe, and S. Yuasa, “Spin-torque diode effect in magnetic tunnel junctions,” Nature, vol. 438, pp. 339-342 (2005).
NPL 5: W. A. Borders, A. Z. Pervaiz, S. Fukami, K. Y. Camsari, H. Ohno, and S. Datta, “Integer factorization using stochastic magnetic tunnel junctions,” Nature, vol. 573, pp. 390-393 (2019).
NPL 6: P. Wadley, B. Howells, J. Železný, C. Andrews, V. Hills, R. P. Campion, V. Novák, K. Olejník, F. Maccherozzi, S. S. Dhesi, S. Y. Martin, T. Wagner, J. Wunderlich, F. Freimuth, Y. Mokrousov, J. Kuneš, J. S. Chauhan, M. J. Grzybowski, A. W. Rushforth, K. W. Edmonds, B. L. Gallagher, T. Jungwirth, “Electrical switching of an antiferromagnet,” Science, vol. 351, pp. 587-590 (2016).
NPL 7: H. Tsai, T. Higo, K. Kondou, T. Nomoto, A. Sakai, A. Kobayashi, T. Nakano, K. Yakushiji, R. Arita, S. Miwa, Y. Otani and S. Nakatsuji, “Electrical manipulation of a topological antiferromagnetic state,” Nature, vol. 580, pp. 608-613 (2020).

### SUMMARY OF INVENTION

### Technical Problem

As described above, there are various types of current control of a magnetic order of a magnetic body. A memory device, a random number generation device, an oscillation device, a wave detection device, and the like using the current control are proposed and verified, and some are put to practical use. On the other hand, there are some problems in these techniques in the related art.

First, since a device using a ferromagnetic body has a macro magnetization, the characteristics thereof change with an external magnetic field, and thus there is a problem in terms of resistance to magnetic field noise. In addition, a frequency of an alternating voltage output by spin-torque oscillation using the ferromagnetic body and a frequency of an input alternating current in which resonance occurs in spin-torque ferromagnetic resonance are fixed by a magnetic characteristic of the ferromagnetic material and a magnetic field applied from outside. In other words, in order to perform variable control of the frequency, there is no choice but to control the external magnetic field, but an increase in production cost and size is unavoidable due to the provision of a mechanism for applying the external magnetic field, and it is difficult to control according to a required specification. Substantially, there is no frequency variability.

In addition, the spin-torque oscillation in the ferromagnetic body (NPL 2), the spin-torque ferromagnetic resonance (NPL 4), and the reversal of the magnetic moment of the non-collinear antiferromagnetic body (NPL 7) require stationary application of the magnetic field from the outside for a stable operation, which is not preferable in practice use.

On the other hand, the rotation of the Neel vector of the collinear antiferromagnetic body (NPL 6) does not require the external magnetic field, but has a small change in a conduction characteristic according to a state and has a problem in generating a sufficient output signal.

In view of the above problems, an object of the invention is to provide an electronic device that can be used as a memory device or a random number generation device capable of outputting a relatively large reading signal, and that can also be used as an oscillation/wave detection device having output/input frequency variability, without requiring an external magnetic field.

### Solution to Problem

An electronic device of the invention has at least the following configurations.

The electronic device includes a body, input terminals, and output terminals, in which the body is configured by laminating a spin-torque generation layer and a non-collinear antiferromagnetic layer on a substrate in such an order or in a reverse order in a laminating direction, the input terminals are disposed on both ends of the spin-torque generation layer in any one direction parallel to a lamination surface, and the non-collinear antiferromagnetic layer has a non-collinear magnetic order in a plane formed by said any direction and the laminating direction.

An electronic device of the invention has at least the following configurations.

An electronic device includes a body, a first terminal, and a second terminal. The body is configured by laminating a spin-torque generation layer, an intermediate layer, and a non-collinear antiferromagnetic layer in such an order or in a reverse order, the spin-torque generation layer has a substantially fixed magnetic structure, and a magnetization direction is defined as an effective magnetization direction thereof, the intermediate layer is formed of a non-magnetic material, the non-collinear antiferromagnetic layer has a non-collinear magnetic order in a plane orthogonal to the magnetization direction, the spin-torque generation layer has a surface opposite to the intermediate layer, the surface being connected to the first terminal, and the non-collinear antiferromagnetic layer has a surface opposite to the intermediate layer, the surface being connected to the second terminal.

As will be described in detail later, the inventions of these electronic devices can be regarded as technically closely related inventions and a group of inventions having a corresponding special technical feature from a viewpoint of utilizing dynamics of a chiral spin structure, which is a unique behavior of a non-collinear antiferromagnetic body.

A method for producing an electronic device according to the invention includes at least the following configurations.

The method includes: placing a substrate on a stage; depositing a spin-torque generation layer on the substrate; depositing a non-collinear antiferromagnetic layer in a state in which a surface of the stage is kept at 300 degrees or higher; performing a heat treatment such that the substrate is heated to 300 degrees or higher; and performing microfabrication.

Further, a method for using the electronic device according to the invention includes at least the following configurations.

The electronic device is characterized by being used as an oscillation device by introducing an alternating current between input terminals, being used as a wave detection device by introducing an alternating current between input terminals, being used as a random number generation device by inputting a pulse current having a pulse width of 10 ns or more between input terminals, or being used as a memory device by inputting a pulse current having a pulse width of 0.1 ns or more and 2 ns or less between input terminals.

### Advantageous Effects of Invention

The electronic device according to the invention operates in no magnetic field, which solves a problem of an oscillation device, a wave detection device, a random number generation device, and a memory device using a ferromagnetic body, a collinear antiferromagnetic body, and a non-collinear antiferromagnetic body in the related art. Moreover, the characteristics of the electronic device according to the invention do not easily change with respect to an external magnetic field, which solves the problem of the oscillation device, the wave detection device, the random number generation device, and the memory device using a ferromagnetic body or non-collinear antiferromagnetic body in the related art.

When the electronic device according to the invention is used as an oscillation device, a frequency of an AC signal to be output can be modulated, which solves a problem of the oscillation device using a ferromagnetic body in the related art.

When the electronic device according to the invention is used as a wave detection device, a frequency of an AC signal that can be detected can be modulated, which solves a problem of the wave detection device using a ferromagnetic body in the related art.

### BRIEF DESCRIPTION OF DRAWINGS

FIG. 1 is a schematic view illustrating a first embodiment (basic structure) of an electronic device according to the invention.

FIG. 2 is a schematic view illustrating names of crystal planes of a hexagonal material.

FIG. 3 is a schematic diagram illustrating a kagome lattice formed on a C-plane of D0₁₉-Mn₃Sn and a chiral spin structure formed thereon.

FIG. 4 is a schematic diagram illustrating an operation principle of the electronic device according to the invention.

FIG. 5 is a schematic diagram illustrating a method of use as an oscillation device of the electronic device according to the invention.

FIG. 6 is a schematic diagram illustrating a method of use as a wave detection device of the electronic device according to the invention.

FIG. 7 is a schematic diagram illustrating a method of use as a random number generation device of the electronic device according to the invention.

FIG. 8 is a schematic diagram illustrating a method of use as a memory device of the electronic device according to the invention.

FIG. 9 is an explanatory diagram of a characteristic (numerical simulation) of the first embodiment.

FIG. 10 is an explanatory diagram of a characteristic (experimental result) of the first embodiment.

FIG. 11 is a schematic diagram illustrating a structure according to a second embodiment of the invention.

FIG. 12 is a schematic diagram illustrating a structure according to a third embodiment of the invention.

FIG. 13 is a schematic diagram illustrating a structure according to a fourth embodiment of the invention.

FIG. 14 is a schematic diagram illustrating a structure according to a fifth embodiment of the invention.

FIG. 15 is a schematic diagram illustrating a structure according to a sixth embodiment of the invention.

### DESCRIPTION OF EMBODIMENTS

Hereinafter, an electronic device according to the invention will be described with reference to the drawings. The drawings are conceptual diagrams created for a purpose of description, and do not necessarily illustrate an exact aspect as implemented.

### First Embodiment: Basic Structure of Electronic Device

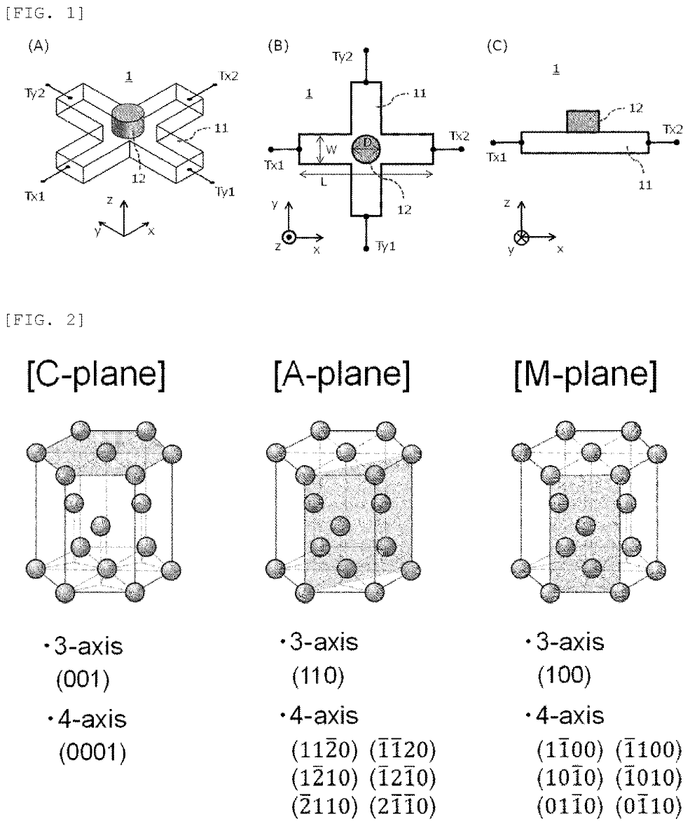

FIG. 1 schematically illustrates a basic structure of an electronic device 1 according to the invention, and can be referred to as a first embodiment. (A) is a perspective view, (B) is a plan view, and (C) is a cross-sectional view. Hereinafter, an XYZ-orthogonal coordinate axis shown in FIG. 1 will be described. A Z-axis represents a substrate perpendicular direction, and X-Y axes are in a substrate plane.

The electronic device 1 according to the invention includes at least a spin-torque generation layer 11 and a non-collinear antiferromagnetic layer 12. The spin-torque generation layer 11 and the non-collinear antiferromagnetic layer 12 are laminated in a Z-axis direction. In FIG. 1, the spin-torque generation layer 11 is disposed on a lower side, that is, closer to the substrate, and such an order may be reversed. In FIG. 1, the spin-torque generation layer 11 and the non-collinear antiferromagnetic layer 12 are provided adjacent to each other, and may not necessarily be adjacent to each other. As long as a technical idea of the invention is not damaged, another layer such as an adjustment layer may be inserted between the spin-torque generation layer 11 and the non-collinear antiferromagnetic layer 12 for a purpose of adjusting an operational characteristic.

In FIG. 1, the spin-torque generation layer 11 has a shape extending in a first direction at least in the substrate plane, and both ends thereof are connected to a first input terminal Tx1 and a second input terminal Tx2. In FIG. 1, the first direction is an X-direction. In an embodiment illustrated in FIG. 1, the spin-torque generation layer 11 is patterned in a cross shape, and both ends in a Y-direction are connected to a first output terminal Ty1 and a second output terminal Ty2. As will be described later, since a pair of positive and negative output signals are generated from the first output terminal Ty1 and the second output terminal Ty2, these terminals are preferably connected to a differential amplifier outside the device.

In the embodiment shown in FIG. 1, the non-collinear antiferromagnetic layer 12 is provided on an intersection of the spin-torque generation layer 11 patterned in the cross shape. The non-collinear antiferromagnetic layer 12 has a cylindrical shape. A width W of the spin-torque generation layer 11 is preferably 20 nm to 400 nm, and a length L of the spin-torque generation layer 11 is preferably 60 nm to 1000 nm. A diameter D of the non-collinear antiferromagnetic layer 12 is preferably 20 nm to 500 nm, and more preferably 20 nm to 200 nm. A difference between W and D is preferably 50 nm or less. A physical factor for determining a preferable design range of D will be described later. In FIG. 1, a planar shape of the non-collinear antiferromagnetic layer 12 is a circular shape, and is not limited to the circular shape actually. For example, the planar shape thereof may be a square shape. When the planar shape is a square shape, a suitable design range of a length of one side is the same as the suitable design range of D described above.

Although not shown in FIG. 1, for a purpose of controlling a crystal orientation of the spin-torque generation layer 11 and the non-collinear antiferromagnetic layer 12 and improving adhesion to the substrate thereof, a base layer, a seed layer, and a buffer layer may be provided on a lower side of the laminated structure, and a cap layer may be provided on an upper side of the laminated structure from a viewpoint of protecting materials in a microfabrication process. In the embodiment shown in FIG. 1, the spin-torque generation layer 11 is extended in the cross shape such that the input terminal and the output terminal can be easily distinguished, and may fall within the same extent of the non-collinear antiferromagnetic layer 12. The above will be understood more deeply in terms of a relation between a plane on which a magnetic order is formed and a current direction, which will be described later.

### (Magnetic Order to be Set and Material of Non-Collinear Antiferromagnetic Layer for Providing the Same)

Next, materials used for the spin-torque generation layer 11 and the non-collinear antiferromagnetic layer 12 in the embodiment shown in FIG. 1 will be described. First, materials that can be used for the non-collinear antiferromagnetic layer 12 will be described. The non-collinear antiferromagnetic layer 12 is formed of a substance having a non-collinear magnetic order. Typical examples include non-collinear antiferromagnetic bodies such as a Mn₃Sn alloy and a Mn₃Ge alloy having a D0₁₉ ordered structure, and a Mn₃Ir alloy and a Mn₃Pt alloy having an L2₁ ordered structure. These substances have a kagome lattice as will be described later, and has a non-collinear magnetic order formed in a kagome plane thereof.

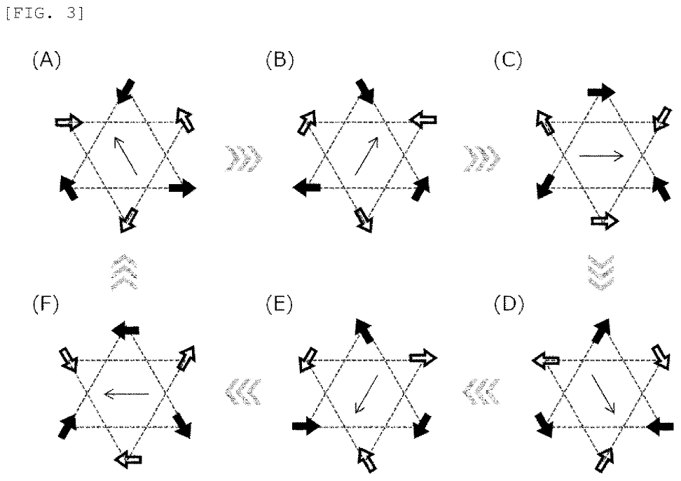

In the embodiment shown in FIG. 1, it is necessary for the non-collinear antiferromagnetic layer 12 to have the non-collinear magnetic order in a plane defined by the laminating direction, that is, a Z-direction, and the first direction, that is, the X-direction, that is, in an X-Z plane. As an example, the above will be described in detail using D0₁₉-Mn₃Sn as an example. D0₁₉ ordered structure is an ordered structure in which a device occupying each site is determined in a hexagonal crystal as shown in FIG. 2. As names of hexagonal planes, a (001) plane in a three-axis representation may be referred to as a C-plane, a (110) plane may be referred to as an A-plane, and a (100) plane may be referred to as an M-plane. FIG. 2 illustrates a relation between the three planes side by side. Further, planes represented by a C-plane, an A-plane, and an M-plane in a four-axis representation are also illustrated in FIG. 2. In the D0₁₉-Mn₃Sn, the C-plane is a kagome plane, and a chiral spin structure, which is a non-collinear magnetic order, is formed. Therefore, when D0₁₉-Mn₃Sn is used for the non-collinear antiferromagnetic layer 12, the C-axis needs to have a component orthogonal to the X-Z plane, and is preferably orthogonal to the X-Z plane. It is unnecessary for such an orientation to be implemented in an entire region of the non-collinear antiferromagnetic layer 12, and it is sufficient that a preferential orientation satisfies the above condition.

FIG. 3 illustrates a specific chiral spin structure that can be taken in a D0₁₉-Mn₃Sn kagome lattice. In the drawing, thick white arrows and thick black arrows indicate stable directions of magnetic moments of Mn atoms located in different layers, respectively. Thin arrows indicate directions of a minute magnetization (a weak ferromagnetic magnetization vector) observed in such a magnetic order state. In a state in which there is a sufficient length in a bulk, that is, in all directions of three-dimensional, six states illustrated in (A) to (F) of FIG. 3 are energetically degenerated.

It is known that Mn₃AN (A=Ga, Ni—Cu) or the like forms a non-collinear magnetic order at room temperature, and can be used for the non-collinear antiferromagnetic layer 12. In addition, in a strict sense, the magnetic order of the non-collinear antiferromagnetic layer 12 can be applied with the invention as long as an electrical conductivity thereof greatly changes in accordance with the state, without necessarily requiring a non-collinear magnetic order. A specific example thereof includes RuO₂. RuO₂ has a collinear magnetic order, and expresses a Hall effect (crystal Hall effect) resulting from symmetry breakage due to a crystal structure thereof.

### (Material of Spin-Torque Generation Layer)

Next, a material that can be used for the spin-torque generation layer 11 will be described. In the embodiment illustrated in FIG. 1, the spin-torque generation layer 11 needs to be a material in which a spin-torque acts on the non-collinear antiferromagnetic layer 12 when a current flows between the first input terminal Tx1 and the second input terminal Tx2. Examples thereof include heavy metals (5d transition metals) such as Hf, Ta, W, Pt, and Ir, and an alloy or a laminated film made of the heavy metals. Another example includes a topological insulator such as a compound of Bi and Se and a compound of Bi and Sb. A spin-torque expression mechanism may be freely selected, and may be a spin Hall effect inside the spin-torque generation layer 11 or a Rashba-Edelstein effect in an interface between the spin-torque generation layer 11 and the non-collinear antiferromagnetic layer 12, and may also be a coupling of a momentum vector (or wave vector) of conduction electrons and the spin resulting from a topological band structure of the spin-torque generation layer.

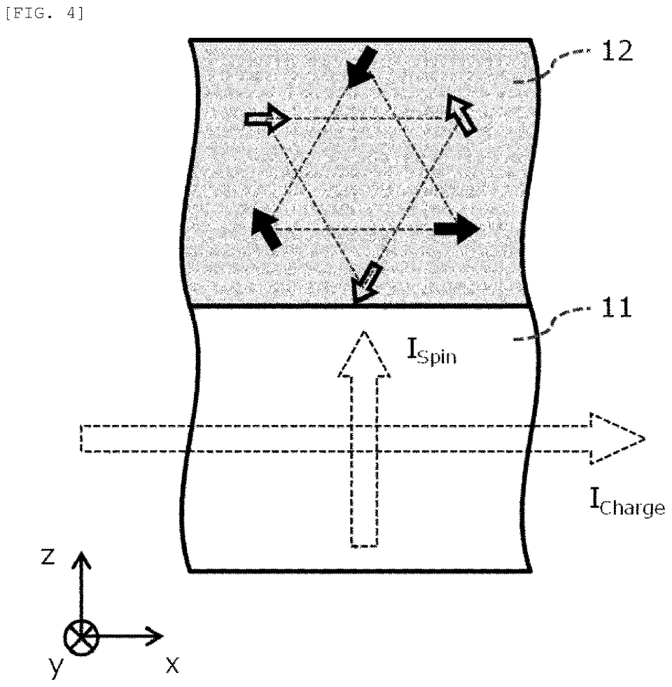

FIG. 4 illustrates a relation between a current and a spin current in a case in which an origin of the spin-torque acting on the non-collinear antiferromagnetic layer 12 is the spin Hall effect in the spin-torque generation layer 11. In the case, a current ICharge flowing through the spin-torque generation layer 11 is introduced in the X-direction, and a spin flow in the Z-direction, that is, a spin current ISpin is generated. The spin current ISpin enters inside of the non-collinear antiferromagnetic layer 12, and exerts a torque on the non-collinear magnetic order. The invention utilizes dynamics of the non-collinear magnetic order induced thereby. The conduction electrons responsible for the spin current generated by the spin Hall effect has a spin polarization in the Y-direction. A sign of the spin polarization is changed depending on a type of the spin-torque generation layer 11 used here, and the invention can be practiced with a material that produces the spin polarization of any sign.

### (Outline of Method for Using Electronic Device)

Next, a method for using the electronic device 1 according to the invention will be described in such an order of being used as an oscillation device, a wave detection device, a random number generation device, and a memory device. In a case of using any device, the dynamics induced in the non-collinear magnetic order in the non-collinear antiferromagnetic layer 12 is utilized when the current is introduced between the first input terminal Tx1 and the second input terminal Tx2. The dynamics utilized here is different from dynamics of a ferromagnetic body, a collinear antiferromagnetic body, and a non-collinear antiferromagnetic body, which have been reported in the related art, and is found by an experiment by inventors of the invention. The dynamics is the relation between the plane in which the magnetic order is formed and the current direction, which is described as “will be described later” in the foregoing text. Thereby, it should be understood that the spin-torque generation layer 11 does not necessarily need to be extended in a cross shape and that it is sufficient to have the same degree of extension as the non-collinear antiferromagnetic layer 12.

FIG. 5 illustrates a situation of operating as an oscillation device. A time change in an input signal, a time change in an output signal, and a time change in a chiral spin structure are schematically illustrated in the order from a top. When the electronic device is used as an oscillation device, a direct current is introduced between the first input terminal Tx1 and the second input terminal Tx2. A sign of the current may be either positive or negative. At this time, when a magnitude of the input current is equal to or larger than a certain threshold, a voltage output from the first output terminal or a voltage output from the second output terminal, or a difference between the voltage output from the first output terminal and the voltage output from the second output terminal oscillates at a constant frequency. That is, an alternating voltage is output. A middle part of FIG. 5 illustrates the time change of the chiral spin structure in a portion surrounded by a dotted rectangle in a lower portion, and a motion in which the weak ferromagnetic magnetization stationarily rotates clockwise or counterclockwise is induced. The drawing illustrates a situation in which the weak ferromagnetic magnetization is rotated in the order of 11:00, 1:00, 3:00, 5:00, 7:00, 9:00, 11:00, 1:00, and so on. A rotation direction is determined by a sign of the spin-torque. The rotation continues as long as the direct input current is introduced, and a magnetic field from outside is not required. A feature indicates an advantage of the electronic device according to the invention. By introducing the direct current between the first input terminal and the second input terminal in this manner, the alternating voltage can be extracted from the first and second output terminals. A frequency of the generated alternating voltage is determined by magnetic anisotropy of the material used for the non-collinear antiferromagnetic layer 12, the Dzyaloshinskii-Moriya interaction constant, and the direct current to be introduced.

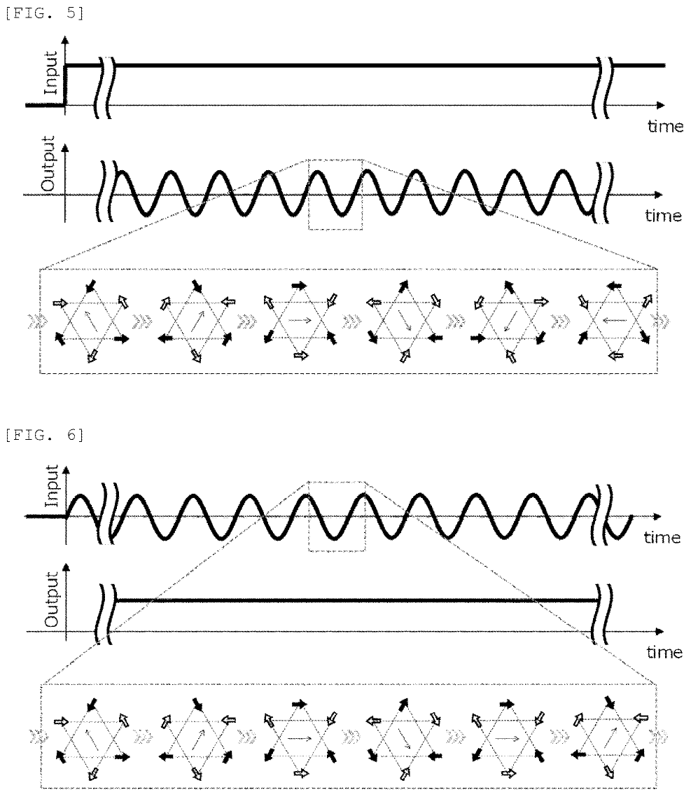

FIG. 6 illustrates a situation of operating as a wave detection device. A time change in an input signal, a time change in an output signal, and a time change in a chiral spin structure are schematically illustrated in the order from a top. When the electronic device is used as a wave detection device, an alternating current is introduced between the first input terminal Tx1 and the second input terminal Tx2. At this time, when an amplitude of the alternating current is equal to or more than a certain value and a frequency satisfies a certain condition, the chiral spin structure and a magnetization direction of the weak ferromagnetism accompanying the chiral spin structure repeat clockwise and counterclockwise motions as shown in a lower portion of FIG. 6. The drawing illustrates a situation in which oscillation occurs in the order of 11:00, 1:00, 3:00, 5:00, 3:00, 1:00, 11:00, 1:00, 3:00, and so on. Actually, the invention can also be implemented when the amplitude is small in the order of 1:00, 3:00, 5:00, 3:00, 1:00, 3:00, 5:00, 3:00, and so on. When the chiral spin structure performs such a motion, a Hall resistance oscillates at the same frequency as the input alternating current. Accordingly, a direct output voltage is obtained. Signs of the output voltage are opposite at the first output terminal and the second output terminal. Therefore, a larger signal can be obtained by connecting the first output terminal and the second output terminal to a differential amplifier. The operation does not require application of the magnetic field from the outside and is advantageous.

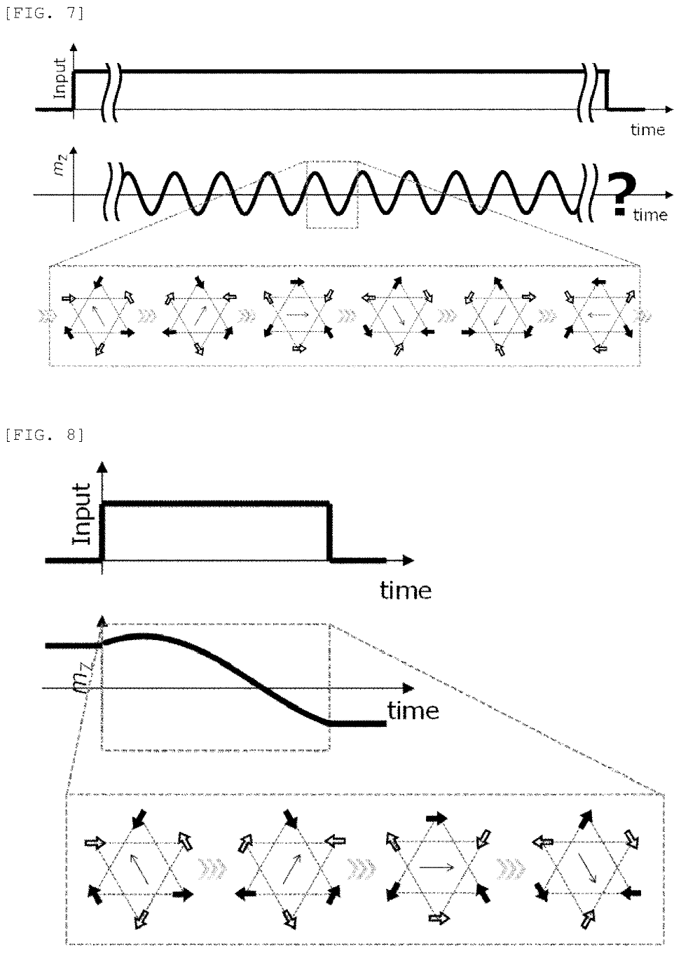

FIG. 7 illustrates a situation of operating as a random number generation device. A time change in the input signal, a time change in a magnetization perpendicular-to-plane component of the weak ferromagnetic, and a time change in the chiral spin structure are schematically illustrated in the order from a top. The dynamics induced in the chiral spin structure in the random number generation device is the same as that of the oscillation device described with reference to FIG. 5. When a pulse current having an amplitude equal to or greater than a certain value and a relatively long pulse width is introduced into the electronic device according to the invention, a phase of rotation of the chiral spin structure is alleviated, and a final state cannot be predicted. When the electronic device is used as a random number generation device, the above matter is used. In general, coherence of a phase each time the dynamics of the magnetic body is induced is lost at the room temperature by about 10 cycles. A time of one cycle of the motion of the chiral spin structure induced by an intensity of a realistic input current is approximately 0.2 ns or more and 4 ns or less as will be described later, and is typically 1 ns. Therefore, depending on a material used and an intensity of the input pulse current, by inputting a rectangular pulse current with a pulse width of 10 ns or more, the chiral spin structure will rotate 10 times or more, and the final state cannot be predicted. That is, after that, an intrinsic physical random number can be extracted by reading the state of the chiral spin structure by any method. FIG. 7 illustrates a case in which a rectangular and positive pulse current is introduced, and a shape and a sign of the pulse width may be freely selected. For example, the pulse may have a trapezoidal shape, or may be a burst pulse of positive and negative oscillation.

FIG. 8 illustrates a situation of operating as a memory device. A time change in the input signal, a time change in weak ferromagnetic magnetization, and a time change in the chiral spin structure are schematically illustrated in the order from the top. An operation method of the memory device is similar to that of the random number generation device described with reference to FIG. 7, but is different from the random number generation device in that the pulse width is extremely short and the final state can be sufficiently controlled. For example, by introducing a pulse current having a half pulse width of one cycle, the state can be switched such that 11:00 is switched to 5:00 and 1:00 is switched to 7:00. FIG. 8 illustrates an example of switching from 11:00 to 5:00. As described above, since the time of one cycle is in a range of 0.2 ns or more and 4 ns or less, the pulse width of the input pulse current is preferably 0.1 ns or more and 2 ns or less. In a case of the memory device, since a toggle operation, that is, storage information is rewritten between 0 and 1, a read operation is performed before the information is written, and a write operation is performed only when the information is different from the information to be stored.

### (Operation Principle of Electronic Device)

An operation principle that is a basis of the events described above will be described. Specifically, the dynamics induced when the spin-torque acts on the chiral spin structure found by the inventors of the invention will be described, whereby the basis of phenomena utilized by the invention, so to speak, laws of nature under the patent law, will be described.

As described with reference to FIG. 3, for example, in a case of Mn₃Sn having a D0₁₉ ordered structure, a C-plane (001 plane) forms a kagome lattice, and six energy-equivalent non-collinear magnetic orders are formed (degenerated). In a case of a thin film in which the C-axis is in the film plane, such as the M-plane orientation film and the A-plane orientation film, degeneracy may be released between (A), (B), (D) and (E) and (C) and (F) in FIG. 3, and an energy level may be split into 4:2. Also in this case, the internal energies of (A), (B), (D), and (E) are substantially equivalent to each other. Here, (A), (B), (D), and (E) have different signs of a film plane direct component of a belly curvature are different, and thus can be electrically distinguished via an abnormal Hall effect or the like.

Now, a case in which the spin-torque acts on the kagome lattice is considered. Here, specifically, as illustrated in FIG. 4, consider a case in which the origin of the spin-torque is the spin Hall effect in the spin-torque generation layer 11. In this case, the spin current ISpin is generated in the Z-direction, and electrons spin-polarized in the Y-direction are injected into the non-collinear antiferromagnetic layer 12. Then, due to the spin-transfer torque, the magnetic moment of each site of the chiral spin structure first rises in the Y-direction, and then rotates on the kagome plane (X-Z plane). In this case, it is important that the rotational directions of the magnetic moments of all the sites are the same. As a result, when the sign of the spin-torque is constant, the rotation in the same direction is continued, and when the sign of the spin-torque oscillates between positive and negative, the chiral spin structure repeats the clockwise and counterclockwise motions following the positive and negative signs. Such the dynamics is apparent by calculation and an experiment performed by the inventors, which will be described later. The oscillation device, the wave detection device, the random number generation device, and the memory device realized by the dynamics, are clearly distinguished from a device using the dynamics of ferromagnetic body, collinear antiferromagnetic body, and non-collinear antiferromagnetic body, which have been reported so far. In particular, the invention should be distinguished from the technique disclosed in NPL 7, which is only common in using non-collinear antiferromagnetic body.

A magnitude of the spin-torque for inducing a rotational motion in the chiral spin structure has a threshold, which is determined by characteristics of the material used for the non-collinear antiferromagnetic layer 12, specifically, the magnetic anisotropy, the Dzyaloshinskii-Moriya interaction, and the like. On the other hand, the magnitude of the spin-torque expressed per current is determined by the material used for the spin-torque generation layer 11. A speed of the rotational motion of the chiral spin structure is determined by a characteristic of the non-collinear antiferromagnetic layer 12 and the magnitude of the applied spin-torque. In the above description, a picture of a case in which the spin-torque acts adiabatically in a form of angular momentum transfer (called anti-damping torque, Slonczewski-like torque, etc.), and the torque acting on the magnetic moment of each site of the chiral spin structure by the current may be an effective magnetic field (called a field-like torque or the like).

As can be seen from the above description, the invention is based on the dynamics of the chiral spin structure of the non-collinear antiferromagnetic layer 12, and thus the non-collinear antiferromagnetic layer 12 preferably has a single domain. From the experiment performed by the inventors, it is apparent that a size of the domain of a Mn₃Sn thin film ordered as D0₁₉ indicating non-collinear antiferromagnetism is about 200 nm. Therefore, the diameter D of the non-collinear antiferromagnetic layer 12 is preferably 200 nm or less. However, actually, the size of the domain of the non-collinear antiferromagnetic body may be changed depending on the material used, the deposition method of the thin film, the substrate, and the like, and a preferred design range of the diameter D of the non-collinear antiferromagnetic layer 12 may also change in response.

### Producing Method and Operation Verification According to First Embodiment

A first embodiment will be described more specifically with reference to a numerical simulation result and an experimental result obtained by the inventors regarding dynamics induced when a spin-torque acts on the chiral spin structure of the non-collinear antiferromagnetic body.

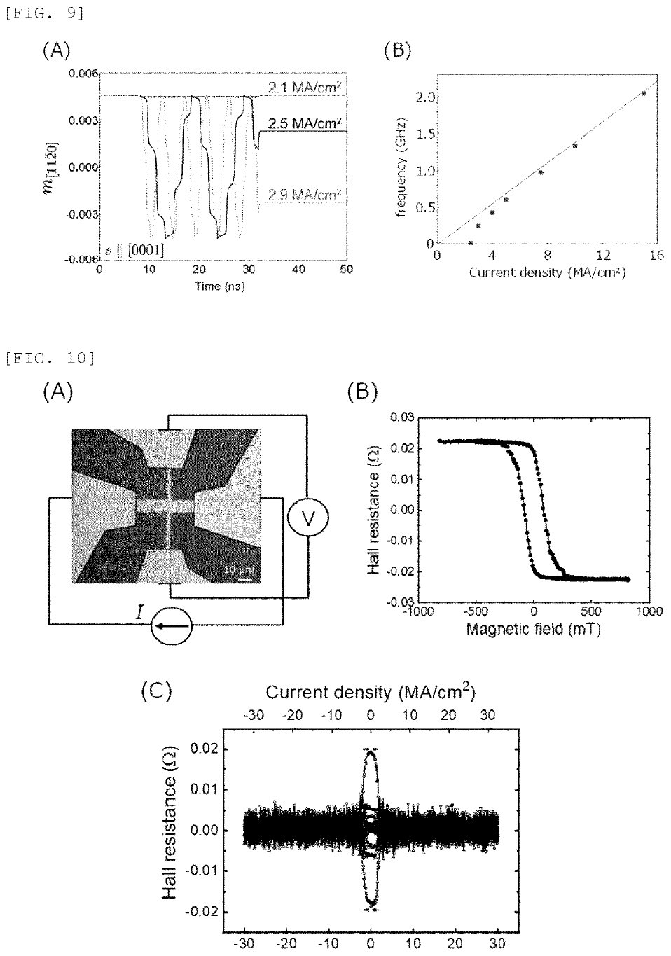

(A) of FIG. 9 is a numerical simulation result of the time change in a film plane vertical direction component of a weak ferromagnetic magnetic moment when the spin-torque acts on the chiral spin structure performed by the inventors. Based on the Landau-Lifshitz-Gilbert equation, time evolution calculation is performed on three sub-lattices of the kagome lattice. A parameter of the material is set by simulating D0₁₉-Mn₃Sn, and it is assumed that kagome plane is in the X-Z plane and a torque is applied in a form of anti-damping torque when the spin is injected in the Y-direction. Conversion of a current density and a spin-torque of an input current is performed using a conversion coefficient predicted when W and Pt are used as the spin-torque generation layer. Calculation results for three types of current density of 2.1 MA/cm², 2.5 MA/cm², and 2.9 MA/cm² are illustrated. The current is introduced between 8 ns and 30 ns. It is found that when the current density is 2.1 MA/cm², no significant change occurs, whereas when the current density is 2.5 MA/cm² or 2.9 MA/cm², the weak ferromagnetic magnetic moment oscillates, and the cycle of the oscillation is shorter as the current density increases. (B) of FIG. 9 illustrates a result of plotting a frequency of the oscillation with respect to the current density of the introduced input current after performing the calculation in a manner illustrated in (A) of FIG. 9. It is found that the oscillation is induced at a certain threshold or more, and the frequency of the oscillation gradually approaches a linear function passing through an origin point. As a result of calculation in a wider range, it is found that the frequency of the oscillation changes within a range of about 250 MHz to 5 GHz within a range of a realistic current density that can be introduced. The inverse number thereof, that is, 4 ns to 0.2 ns corresponds to a rotation cycle of the chiral spin structure described above, whereby the pulse width of the input pulse current used for the memory device or the random number generation device is determined.

In this way, a matter that the oscillation frequency can be changed with a single device without applying an external magnetic field is a notable feature not found in the oscillation device using the ferromagnetic body in the related art, and provides an oscillation device with a variable output frequency and a wave detection device with a variable frequency that can detect waves according to the invention.

FIG. 10 illustrates experiment results obtained by the inventors. A laminated film used in the present experiment is deposited on a MgO (110) substrate. A film configuration includes W (3 nm), Ta (1 nm), Mn₃Sn (8.3 nm), and Pt (4 nm) from the substrate. Wa/Ta layers correspond to the spin-torque generation layer 11, and the Mn₃Sn corresponds to the non-collinear antiferromagnetic layer 12. Pt corresponds to a second spin-torque generation layer 13 described in a third embodiment. It is confirmed that an equivalent characteristic can be obtained even when a film thickness of the W layer is changed in a range of 1 nm to 10 nm and the Ta layer is changed in a range of 0.5 nm to 3 nm. It is confirmed that the equivalent characteristic can be obtained even when the film thickness of Mn₃Sn is increased to about 50 nm. The deposition of each layer is performed by DC magnetron sputtering, the substrate is placed on a stage of an apparatus, and then each layer is deposited. When the Mn₃Sn layer is formed, the stage is heated to 400 degrees. A temperature of the stage is preferably set to 300 degrees or more, and more preferably set to a range of 350 degrees to 500 degrees. It is also found from another experiment that it is preferable to heat the stage when depositing the W layer and the Ta layer. After the deposition of the laminated film containing Mn₃Sn, heat treatment is performed at 500 degrees for 1 hour. A temperature of the heat treatment is preferably 300 degrees or more, more preferably 350 degrees to 600 degrees. From X-ray diffraction and observation of a cross-sectional electron microscope, it is confirmed that Mn₃Sn is ordered as D0₁₉ and is oriented to an M-plane. A crystal orientation relation is that a [001] direction of the MgO substrate is parallel to a [0001] direction of Mn₃Sn. After the deposition of the thin film, microfabrication is performed using photolithography, argon ion milling, or the like.

(A) of FIG. 10 illustrates a scanning electron microscope image and a measurement circuit of the measured device. In the device, in order to perform a simple experiment, the spin-torque generation layer 11 and the non-collinear antiferromagnetic layer 12 are patterned into the same shape, and a cross portion at a center of a photograph corresponds to the region. Left and right terminals respectively correspond to the first input terminal Tx1 and the second input terminal Tx2, and upper and lower terminals respectively correspond to the first output terminal Ty1 and the second output terminal Ty2. The terminals are formed such that a line segment connecting the first input terminal Tx1 and the second input terminal Tx2 is in a direction orthogonal to the [001] direction of the MgO substrate, and a line segment connecting the first output terminal Ty1 and the second output terminal Ty2 is parallel to the [001] direction of the MgO substrate. In order to simplify a sample preparation process, the width W of the spin-torque generation layer 11 is set to 10 μm, and a width of a Hall probe extending toward the output terminal is set to 3 μm. Therefore, the structure is such that a state of the chiral spin structure in a region of 10×3 μm² of the non-collinear antiferromagnetic layer 12 is measured. As described above, the size of the domain is 200 nm, and thus is a size including a plurality of domains.

(B) of FIG. 10 illustrates a change in the Hall resistance when the magnetic field is swept in a vertical direction. It means that a high (low) Hall resistance value in a negative (positive) magnetic field, and the Hall effect is derived from topology of the chiral spin structure of Mn₃Sn in a wave number space, and thus it can be confirmed that Mn₃Sn forms the chiral spin structure as illustrated in FIG. 3.

(C) of FIG. 10 illustrates a relation between a Hall resistance and an applied current (density) when the Hall resistance is measured after the weak ferromagnetic magnetization of the chiral spin structure is initialized in an upward direction and a downward direction by using the magnetic field in the vertical direction and then the current pulse of the pulse width of 100 msec is introduced in a positive direction and a negative direction. As described above, in the sample, since a plurality of domains are simultaneously measured, the total of the domains is reflected in a measurement result. Referring to the drawing, it is found that the Hall resistance value transits to a vicinity of a center at a certain threshold or more. It can be understood that a plurality of domains are randomized in a time sufficiently longer than the cycle of the dynamics of the chiral spin structure, which is 100 msec, and after the current pulse is applied, each magnetic domain is settled in one of six stable states, and the Hall resistance value in the vicinity of the center is observed as an average.

In the first embodiment shown in FIG. 1, after the operation principle is described, a use condition or the like is described, and the electronic device according to the invention can be used more effectively by modifying the structure shown in FIG. 1. As a matter of course, these aspects also belong to the embodiments of the invention. Hereinafter, a second embodiment to a sixth embodiment will be described. An item attached to a heading simply indicates the characteristic properties or characteristic structures of the respective embodiments.

### Second Embodiment: Use of Synchronization

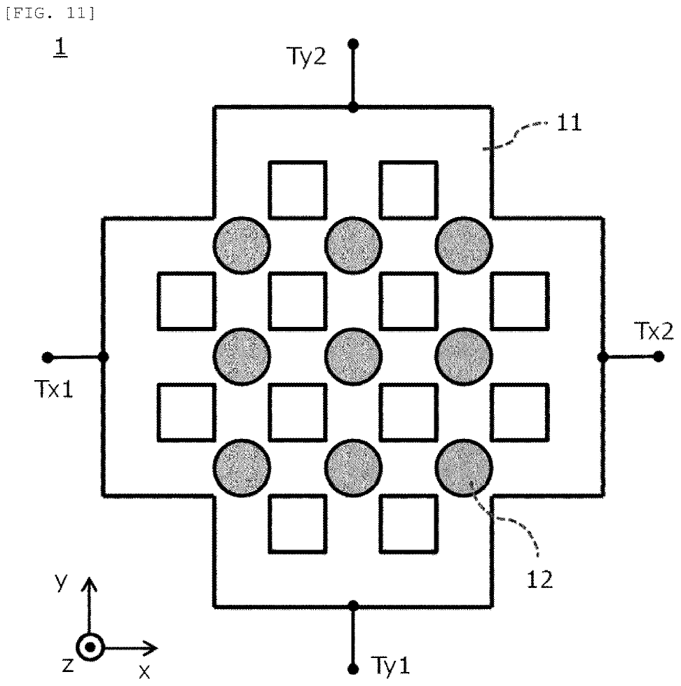

FIG. 11 is an X-Y plane view schematically showing a structure according to a second embodiment. In the second embodiment, an electronic device is effective when used as an oscillation device and a wave detection device. In the second embodiment, a plurality of dots of the non-collinear antiferromagnetic layer 12 are provided, and are electrically connected to each other. A high-frequency electric signal is output along with a motion of the chiral spin structure in the plurality of provided dots of the non-collinear antiferromagnetic layer 12. The output high-frequency electrical signal reaches other dots of the non-collinear antiferromagnetic layer 12. As a result of these combined actions, a phenomenon similar to synchronous oscillation due to a lock of a phase of magnetization of a ferromagnetic body reported in NPL 3 is also induced in the chiral spin structure of the non-collinear antiferromagnetic body. Accordingly, an alternating voltage having a narrow frequency spectrum and a high intensity, that is, a high Q value, is output when the electronic device is the oscillation device. When the electronic device is the wave detection device, it is possible to obtain a high output signal by selectively detecting only an input signal in a narrower frequency range.

### Third Embodiment: HM/NCAFM/HM Laminated Structure

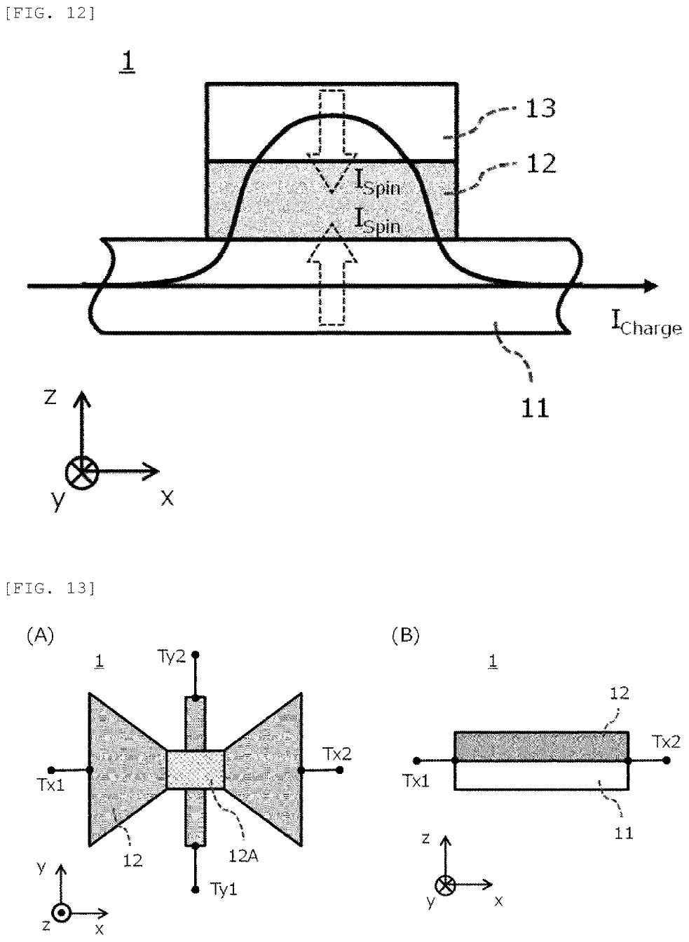

FIG. 12 is an X-Z cross-sectional view schematically illustrating a structure of a third embodiment. The third embodiment is useful for any of an oscillation device, a wave detection device, a random number generation device, and a memory device. In the third embodiment, a surface of the non-collinear antiferromagnetic layer 12 opposite to the spin-torque generation layer 11 is connected to the second spin-torque generation layer 13. A material that can be used for the second spin-torque generation layer 13 is the same as the material that can be used for the spin-torque generation layer 11 described above, and thus is omitted. The second spin-torque generation layer 13 generates a spin-torque acting on the non-collinear antiferromagnetic layer 12 when an input current is introduced, and a direction thereof is the same direction as a spin-torque generated by the spin-torque generation layer 11. Accordingly, a stronger spin-torque can be applied to the chiral spin structure of the non-collinear antiferromagnetic layer 12, and an efficient operation can be implemented.

In FIG. 12, both of the spin-torque generation layer 11 and the second spin-torque generation layer 13 express the spin Hall effect, and a direction of the current ICharge and a direction of the spin current ISpin are illustrated by arrows when a sign of the spin Hall effect is reversed. As illustrated, when electrical conduction of the spin-torque generation layer 11, the non-collinear antiferromagnetic layer 12, and the second spin-torque generation layer 13 is metallic, a part of the input current flows through the second spin-torque generation layer 13 in the X-direction. The current generates the spin current ISpin. When effective spin Hall angles of the spin-torque generation layer 11 and the second spin-torque generation layer 13 are opposite to each other, electrons spin-polarized in the same direction flow into the non-collinear antiferromagnetic layer 12, and a stronger spin-torque acts. Therefore, a large output signal can be obtained with a lower current, a lower voltage, and a lower power as long as an electronic device is the oscillation device or the wave detection device. When the electronic device is a random number generation device or a memory device, a state can be updated with the lower current, the lower voltage, and the lower power. In the embodiment described with reference to FIG. 10, W/Ta corresponds to the spin-torque generation layer 11 and Pt corresponds to the second spin-torque generation layer 13. It is known that W/Ta has a negative spin Hall angle and Pt has a positive spin Hall angle, whereby it is designed such that a large torque acts on the Mn₃Sn layer.

### Fourth Embodiment: Narrowed Structure

FIG. 13 is an X-Y plane view and an X-Z cross-sectional view illustrating a structure according to a fourth embodiment. The previous embodiments have shown an example in which the non-collinear antiferromagnetic layer 12 has a circular shape in the X-Y plane and is formed to fit within the spin-torque generation layer 11. However, in the fourth embodiment, the non-collinear antiferromagnetic layer 12 is patterned into the same shape as the spin-torque generation layer 11 by devising the shape.

In the fourth embodiment, a narrowed portion 12A is formed in the non-collinear antiferromagnetic layer 12. Since the narrowed portion 12A has a width narrower than the other regions, a current density increases when a current is introduced between the first input terminal Tx1 and the second input terminal Tx2. Accordingly, dynamics of a chiral spin structure is induced only in the narrowed portion 12A, and nothing occurs in other regions. Therefore, when the narrowed portion 12A is sufficiently small, the single domain can be substantially controlled by the current. For this reason, a line width of the non-collinear antiferromagnetic layer 12 in the narrowed portion 12A is preferably 200 nm or less.

In the fourth embodiment, since the non-collinear antiferromagnetic layer 12 and the spin-torque generation layer 11 can be patterned simultaneously, the number of steps can be reduced, and a producing cost can be reduced. Actually, it is essential that the current density is concentrated in the narrowed portion 12A, and in that sense, the spin-torque generation layer 11 and the non-collinear antiferromagnetic layer 12 do not necessarily have the same shape.

### Fifth Embodiment: TMR Read

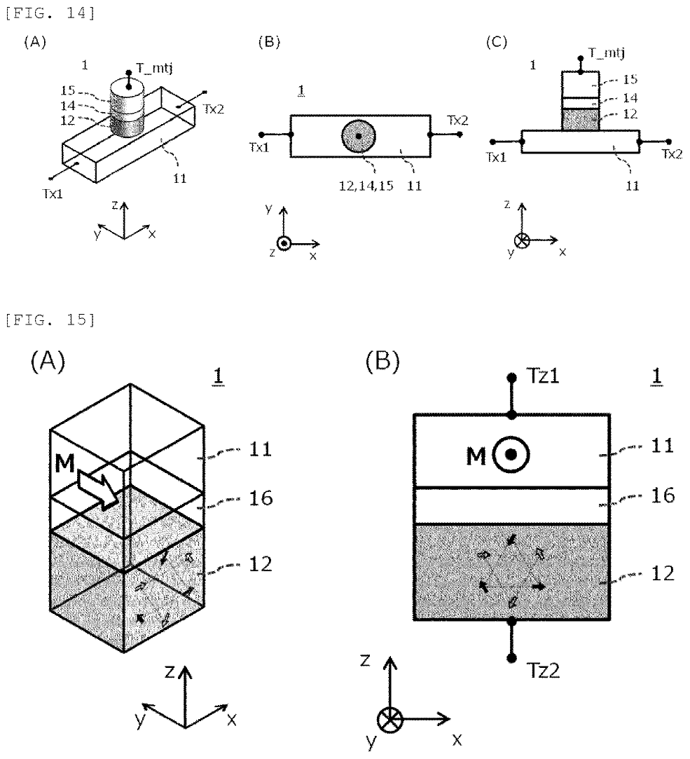

FIG. 14 is an X-Y-Z perspective view, an X-Y plane view, and an X-Z cross-sectional view illustrating a structure according to a fifth embodiment. The previous embodiments have shown a form in which the first output terminal Ty1 and the second output terminal Ty2 are provided by a fact that a state of a chiral spin structure of the non-collinear antiferromagnetic layer 12 can be electrically detected through an anomalous Hall effect is mainly used, whereas in the fifth embodiment, only one output terminal is provided here to detect a state of the chiral spin structure of the non-collinear antiferromagnetic layer 12 using a tunnel magnetoresistive effect. The embodiment is effective mainly in a random number generation device and a memory device.

In the fifth embodiment, a tunnel barrier layer 14 is provided to be connected to a surface of the non-collinear antiferromagnetic layer 12 opposite to the spin-torque generation layer 11, and a reference layer 15 is provided adjacent to a surface of the tunnel barrier layer 14 opposite to the non-collinear antiferromagnetic layer 12. An insulator such as MgO, Al₂O₃ can be used for the tunnel barrier layer 14. The reference layer 15 is formed of a magnetic material, and may use a ferromagnetic body or a non-collinear antiferromagnetic body. A magnetic structure of the magnetic material used for the reference layer 15 is substantially fixed. In FIG. 14, the spin-torque generation layer 11, the non-collinear antiferromagnetic layer 12, the tunnel barrier layer 14, and the reference layer 15 are provided in the order from the substrate, and the order may be reversed. A magnetic tunnel junction is formed by the non-collinear antiferromagnetic layer 12, the tunnel barrier layer 14, and the reference layer 15. Then, a state of the non-collinear antiferromagnetic layer 12 is detected by the tunnel magnetoresistive effect in the magnetic tunnel junction. Compared to a method using the anomalous Hall effect, the magnetic tunnel junction can be formed in a smaller area, and since the tunnel magnetoresistive effect generally provides a larger electric signal output than the anomalous Hall effect, reading in a stable state is possible. The non-collinear antiferromagnetic layer 12 and the tunnel barrier layer 14 are formed adjacent to each other in FIG. 14, and do not necessarily need to be adjacent to each other. A ferromagnetic layer may be inserted between the non-collinear antiferromagnetic layer 12 and the tunnel barrier layer 14 for a purpose of improving a read characteristic due to the tunnel magnetoresistive effect. For readout using the tunnel magnetoresistive effect, a surface of the reference layer 15 opposite to the tunnel barrier layer 14 is connected to a tunnel electrode terminal T_mtj.

Next, in the second embodiment to the fifth embodiment described above, the spin-torque generation layer 11, which is a generation source of the spin-torque acting on the non-collinear magnetic structure in the non-collinear antiferromagnetic layer 12, is provided adjacent to the non-collinear antiferromagnetic layer 12, and a spin current is generated by a phenomenon derived from a spin-orbit interaction such as the spin Hall effect. That is, these embodiments are all subordinate to the first embodiment. The first embodiment discloses that the adjustment layer may be provided, and the inventors of the invention have also obtained the advantageous aspect of providing the intermediate layer not for adjustment, but in a more positive sense. The aspect will be described below.

### Sixth Embodiment: Spin Injection Type

FIG. 15 is an X-Y-Z perspective view and an X-Z cross-sectional view illustrating a structure according to a sixth embodiment. The sixth embodiment uses a fact that an intermediate layer 16 is provided adjacent to the non-collinear antiferromagnetic layer 12, the spin-torque generation layer 11 is provided adjacent to the intermediate layer 16 on a surface opposite to the non-collinear antiferromagnetic layer 12, a spin polarization current is generated by a current passing through the three layers, and the spin polarization current acts on the non-collinear magnetic order of the non-collinear antiferromagnetic layer 12. One of the spin-torque generation layer 11 and the non-collinear antiferromagnetic layer 12 is connected to a first terminal Tz1, and the other is connected to a second terminal Tz2. In FIG. 15, the spin-torque generation layer 11 is connected to the first input terminal Tz1, the non-collinear antiferromagnetic layer 12 is connected to the second input terminal Tz2, and a relation between them is freely selected. In addition, in FIG. 15, the non-collinear antiferromagnetic layer 12, the intermediate layer 16, and the spin-torque generation layer 11 are laminated in such an order from the substrate, and the order may be reversed.

The sixth embodiment operates by introducing an input current between the first terminal and the second terminal. The intermediate layer 16 is made of a non-magnetic material. A metal such as Au, Ag, Cu, or Ru may be used, and an insulator such as MgO, Al₂O₃ may be used. When a current is introduced into the spin-torque generation layer 11, the spin-torque generation layer 11 needs to be a material that is spin-polarized. For example, a ferromagnetic body has the above function. When the spin-torque generation layer 11 is implemented by the ferromagnetic body, a direction of magnetization M is substantially fixed in a second direction. In FIG. 15, the second direction is the Y-direction. The non-collinear antiferromagnetic layer 12 has a non-collinear magnetic order in a plane orthogonal to the second direction (the X-Z plane in FIG. 15).

An operation principle in the sixth embodiment will be described. In the sixth embodiment, the input current is introduced between the first terminal Tz1 and the second terminal Tz2. In common with the previous embodiments, a direct current is used for the oscillation device, an alternating current is used for the wave detection device, a relatively long pulse current is used for the random number generation device, and a sufficiently short pulse current is used for the memory device. The sixth embodiment is characterized in that a spin polarization current is injected into the non-collinear antiferromagnetic layer 12 by passing the current through the spin-torque generation layer 11. As an example, as shown in FIG. 15, a case is considered in which the second terminal Tz2, the non-collinear antiferromagnetic layer 12, the intermediate layer 16, the spin-torque generation layer 11, and the first terminal Tz1 are provided in such an order from the substrate, and the current flows from the second terminal Tz2 to the first terminal Tz1. At this time, conduction electrons flow from the first terminal Tz1 to the second terminal Tz2. When the current passes through the spin-torque generation layer 11, the current interacts with the magnetization of the spin-torque generation layer 11 and is spin-polarized in the Y-direction. The electrons spin-polarized flow into the non-collinear antiferromagnetic layer 12 through the intermediate layer 16. After that, as described with reference to FIGS. 5 to 8, rotation of the chiral spin structure formed in the X-Z plane occurs in the non-collinear antiferromagnetic layer 12.

The spin-torque generation layer 11 does not necessarily have to be a ferromagnetic body as long as an effective magnetization for generating the spin polarization current may be oriented in the second direction. The effective magnetization may be induced by topology of wave number space.

The sixth embodiment may use any method for extracting an output signal and a method of providing an output terminal. For example, when an output is obtained by using an anomalous Hall effect as in the first embodiment described with reference to FIG. 1, the current is allowed to flow in one direction in a film plane (for example, the X-direction) with respect to the non-collinear antiferromagnetic layer 12, and an output signal can be extracted as a voltage generated in a direction orthogonal to the one direction (for example, the Y-direction). In this case, a pair of current input terminals and a pair of output terminals for extracting the output signal in a form of being connected to the non-collinear antiferromagnetic layer 12 are provided to be orthogonal to each other. On the other hand, when the output is performed using the tunnel magnetoresistance effect as in the fifth embodiment described with reference to FIG. 14, the first terminal Tz1 and the second terminal Tz2 serve as the output terminals as they are.

### Advantageous Effects with Respect to the Related Art

Regarding advantageous effects of the invention with respect to the related art, for example, when used as an oscillation device, superiority thereof can be better understood by considering the advantages in two stages including an advantage in a first stage obtained by widely using a spintronics technique including a ferromagnetic body and the like from a device well known as an oscillation device or a crystal oscillator based on CMOS, and an advantage in a second stage obtained from a characteristic configuration of the invention.

In the first stage, a size of a device can be overwhelmingly smaller to be less than or equal to 1/1000 of the technique in the related art, and the current to be introduced can also be overwhelmingly smaller. In the second stage, it is possible to stably use in a wide magnetic field range, and a special method for applying a magnetic field is not required, which is already described, and also leads to frequency variability.

In summary, the effects of the invention can realize an electronic device having a high performance and multiple functions, such as an integration degree, energy saving, stability, and frequency variability.

As described above, the electronic device according to the embodiments of the invention is described in detail with reference to the drawings, the specific configuration is not limited to the embodiments, and design changes and the like within a range not departing from the gist of the invention are also included in the invention. For example, the second to sixth embodiments can be used in combination with each other within a range that does not impair the mechanism relating to the dynamics of the non-collinear magnetic order to be used in the invention.

In particular, a material, a film thickness dimension, and the like are not incapable of exhibiting a desired function unless limited to the embodiments disclosed herein, but can be used as long as being obtained by laminating a layer in which a non-collinear magnetic order is formed and a layer in which spin-torque can be expressed.

### REFERENCE SIGNS LIST

1: electronic device
11: spin-torque generation layer
12: non-collinear antiferromagnetic layer
12A: narrowed portion
13: second spin-torque generation layer
14: tunnel barrier layer
15: reference layer
16: intermediate layer

1. An electronic device comprising:
a body;
input terminals; and
output terminals, wherein
the body is configured by laminating a spin-torque generation layer and a non-collinear antiferromagnetic layer on a substrate in such an order or in a reverse order in a laminating direction,
the input terminals are disposed on both ends of the spin-torque generation layer in any one direction parallel to a lamination surface, and
the non-collinear antiferromagnetic layer has a non-collinear magnetic order in a plane formed by said any one direction and the laminating direction.

2. The electronic device according to claim 1, wherein
the output terminals are disposed at both ends of the spin-torque generation layer in a direction substantially orthogonal to said any one direction.

3. The electronic device according to claim 1, further comprising:
a tunnel barrier layer; and
a reference layer, wherein
the tunnel barrier layer is connected to a surface of the non-collinear antiferromagnetic layer opposite to the spin-torque generation layer,
the reference layer is connected to a surface of the tunnel barrier layer opposite to the non-collinear antiferromagnetic layer, and
the output terminals are disposed in the reference layer.

4. An electronic device comprising:
a body;
a first terminal; and
a second terminal, wherein
the body is configured by laminating a spin-torque generation layer, an intermediate layer, and a non-collinear antiferromagnetic layer in such an order or in a reverse order,
the spin-torque generation layer has a substantially fixed magnetic structure, and a magnetization direction is defined as an effective magnetization direction thereof,
the intermediate layer is formed of a non-magnetic material,
the non-collinear antiferromagnetic layer has a non-collinear magnetic order in a plane orthogonal to the magnetization direction,
the spin-torque generation layer has a surface opposite to the intermediate layer, the surface being connected to the first terminal, and
the non-collinear antiferromagnetic layer has a surface opposite to the intermediate layer, the surface being connected to the second terminal.

5. The electronic device according to claim 1, wherein
the electronic device is used as an oscillation device, a wave detection device, a random number generation device, or a memory device.

6. The electronic device according to claim 1, wherein
the spin-torque generation layer contains any one of Ta, W, Hf, Pt, or Ir.

7. The electronic device according to claim 1, wherein
the non-collinear antiferromagnetic layer is formed of any one of an alloy containing Mn and Sn, an alloy containing Mn and Ge, an alloy containing Mn and Ir, or an alloy containing Mn and Pt.

8. The electronic device according to claim 1, wherein
the non-collinear antiferromagnetic layer has a diameter of 200 nm or less.

9. The electronic device according to claim 1, wherein
a plurality of the non-collinear antiferromagnetic layers are provided and electrically connected to each other, and
the electronic device is used as an oscillation device or a wave detection device.

10. The electronic device according to claim 1, further comprising:
a second spin-torque generation layer, wherein
the second spin-torque generation layer is provided adjacent to a surface of the non-collinear antiferromagnetic layer opposite to the spin-torque generation layer, and
the electronic device is used as an oscillation device or a wave detection device.

11. A method for producing the electronic device according to claim 1, the method comprising:
placing a substrate on a stage;
depositing a spin-torque generation layer on the substrate;
depositing a non-collinear antiferromagnetic layer in a state in which a surface of the stage is kept at 300 degrees or higher;
performing a heat treatment such that the substrate is heated to 300 degrees or higher; and
performing microfabrication.

12. A method for using the electronic device according to claim 1 as an oscillation device, the method comprising:
introducing a direct current between the input terminals.

13. A method for using the electronic device according to claim 1 as a wave detection device, the method comprising:
introducing an alternating current between the input terminals.

14. A method for using the electronic device according to claim 1 as a random number generation device, the method comprising:
inputting a pulse current having a pulse width of 10 ns or more between the input terminals.

15. A method for using the electronic device according to claim 1 as a memory device, the method comprising:
inputting a pulse current having a pulse width of 0.1 ns or more and 2 ns or less between the input terminals.
